(19) United States
(12) Patent Application Publication
(10) Pub. No.: US 2025/0139348 A1
(43) Pub. Date: May 1, 2025

(54) METHOD AND COMPUTING DEVICE FOR AUTOMATICALLY ROUTING CIRCUIT LAYOUT PLAN OF METAL LAYER OF INTERPOSER

(71) Applicant: Intel Corporation, Santa Clara, CA (US)

(72) Inventors: Victoria KOLESOV, Pacific Grove, CA (US); Andrey DASHKOV, Beaverton, OR (US)

(21) Appl. No.: 18/499,320

(22) Filed: Nov. 1, 2023

(51) Int. Cl. G06F 30/392

(52) U.S. Cl. CPC G06F 30/392

(57) ABSTRACT

Disclosed herein is a method for automatically routing a circuit layout of a metal layer of an interposer is provided. The method may include identifying anchor points of the metal layer; sorting the anchor points by location; determining neighbouring anchor points of a same supply net from the location of the anchor points; and creating vertical straps on the circuit layout plan through the neighbouring anchor points of the same supply net.

### TECHNICAL FIELD

This disclosure generally relates to a method and a computing device for automatically routing a circuit layout of a metal layer of an interposer.

### BACKGROUND

Due to the high demand for interposers, a circuit layout plan of a metal layer of an interposer needs to be completed on predictable schedule to cope with the high demand. Package Side Metal (PSM) routing automation was never enabled previously, because the metal layer circuit layout has unique rules which makes it difficult for automation. Thus, previous metal layer circuit layout plan is typically done manually by a layout engineer. However, manual routing requires high effort and time and the layout circuits often cannot be reused due to design changes of the interposer.

Therefore, a solution for automatic routing of a circuit layout plan of a metal layer of an interposer is desired.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed. In the following description, various aspects are described with reference to the following drawings, in which:

FIG. 1 shows a schematic diagram illustrating a computing device;

FIG. 2 illustrates a flow diagram for a method checking for SOA violations; and

FIGS. 3A to 3D show exemplary circuit layouts of a metal layer of an interposer.

### DESCRIPTION

The following detailed description refers to the accompanying drawings that show, by way of illustration, specific details and aspects in which the invention may be practiced.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The words “plural” and “multiple” in the description and in the claims expressly refer to a quantity greater than one. Accordingly, any phrases explicitly invoking the aforementioned words (e.g., “a plurality of (objects)”, “multiple (objects)”) referring to a quantity of objects expressly refer to more than one of the said objects. The terms “group (of)”, “set (of)”, “collection (of)”, “series (of)”, “sequence (of)”, “grouping (of)”, etc., and the like in the description and in the claims, if any, refer to a quantity equal to or greater than one, i.e. one or more.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. Any type of information, as described herein, may be handled for example via one or more processors in a suitable way, e.g. as data.

The terms “processor” or “controller” as, for example, used herein may be understood as any kind of entity that allows handling data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

The term “module” detailed herein refers to, or forms part of, or includes an Application Specific Integrated Circuit (ASIC); an electronic circuit; a combinational logic circuit; a field programmable gate array (FPGA); a processor (shared, dedicated, or group) that executes code; other suitable hardware components that provide the described functionality; or a combination of some or all of the above, such as in a system-on-chip. The term module may include memory (shared, dedicated, or group) that stores code executed by the processor.

A processor, controller, and/or circuit detailed herein may be implemented in software, hardware, and/or as a hybrid implementation including software and hardware.

The term “system” (e.g., an artificial intelligence system, a machine learning system, a computing system, etc.) detailed herein may be understood as a set of interacting elements, of which the elements can be, by way of example and not of limitation, one or more mechanical components, one or more electrical components, one or more instructions (e.g., encoded in storage media), and/or one or more processors, and the like.

The term “semiconductor device” as used herein refers to both the singular and plural form of the words, and accordingly can refer to both a single semiconductor device and multiple semiconductor devices.

An advantage of the present disclosure may include improved or reduced time taken to obtain a circuit layout plan of an interposer. Instead of manually planning by a layout engineer, a circuit layout plan of the interposer may be obtained by identifying anchor points of the interposer based on proximity and connectivity. The circuit layout plan by the processor may include details of horizontal straps, vertical straps and diagonal straps, wherein straps may be electrical connectors between the anchor points of the interposer. The details may include location, size, and length of the electrical connectors with respect to the anchor points.

Other advantages include early power grid reliability verification, early Process Design Kit readiness check, early floorplan quality check.

These and other aforementioned advantages and features of the aspects herein disclosed will be apparent through reference to the following description and the accompanying drawings. Furthermore, it is to be understood that the features of the various aspects described herein are not mutually exclusive and can exist in various combinations and permutations.

The present disclosure generally relates to a method for automatically routing a circuit layout plan of a metal layer of an interposer. The method may include: identifying anchor points of the metal layer; sorting the anchor points by location; determining neighbouring anchor points of a same supply net from the location of the anchor points; and creating vertical straps on the circuit layout plan through the neighbouring anchor points of the same supply net.

The present disclosure generally relates to a computing device for automatically routing a circuit layout of a metal layer of an interposer. The computing device may include one or more processors configured to: identify anchor points of the metal layer; sort the anchor points by location; determine neighbouring anchor points of a same supply net from the location of the anchor points; and create vertical straps on the circuit layout plan through the neighbouring anchor points of the same supply net.

To more readily understand and put into practical effect, the present device, computing device, method, and other particular aspects will now be described by way of examples and not limitations, and with reference to the figures. For the sake of brevity, duplicate descriptions of features and properties may be omitted.

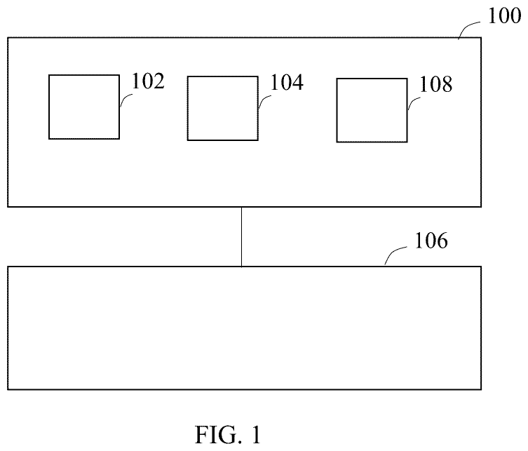

FIG. 1 shows a schematic diagram illustrating a computing device 100.

In an aspect, the computing device 100 may include one or more processors 102. The computing device may include an input/output module 104 for communication with an interposer 106. The computing device may also include a non-transitory computer readable medium which may be a part of the processor 102.

In an aspect, the non-transitory computer readable medium may store a computer executable code which may include instructions stored therein that when executed by the processor 102 cause the processor 102 to automatically provide a routing of a circuit layout plan of a metal layer of an interposer 106. The circuit layout plan may be a schematic diagram showing how different parts of the circuit should be connected. The circuit layout plan may include anchor points such as through-silicon vias and package side bumps, as well as straps which may represent electrical connectors for electrical communication between the different anchor points.

In an aspect, the processor 102 may receive information regarding the metal layer of the interposer 106 from an optical instrument 108 for example a camera electrically connected to the semiconductor device 106. The optical instrument may be configured to provide location information of the anchor points to the one or more processors. The information may include locations of various points on the metal layer.

In an aspect, the processor 102 may identify anchor points of the metal layer using the information from the optical instrument 108. In an aspect, the anchor points of the metal layer may include through-silicon vias and/or package side bumps on the metal layer.

In an aspect, the processor 102 may sort the anchor points by location. The processor 102 may determine neighbouring anchor points of a same supply net from the location of the anchor points. Neighbouring anchor points may be anchor points that are location next to each other in the metal layer. The distance of neighbouring anchor points may be for example, 105 um to 115 um e.g., 110.16 um.

In an aspect, the processor 102 may create vertical straps on the circuit layout plan through the neighbouring anchor points of the same supply net. The vertical straps may be electrical connectors in a vertical direction. The vertical straps may facilitate power communication between neighbouring anchor points of the same supply net.

In an aspect, the processor 102 may create vertical straps on the circuit layout plan through a through-silicon via and a neighbouring package side bump of the same supply net.

In an aspect, the processor 102 may also create vertical straps on the circuit layout plan through multiple neighbouring through-silicon vias the same supply net.

In an aspect, the processor 102 may also create vertical straps on the circuit layout plan through multiple neighbouring package side bumps of the same supply net.

In an aspect, the processor 102 may connect multiple neighbouring through-silicon vias with first horizontal straps on the circuit layout plan. The first horizontal straps may facilitate power communication between neighbouring through-silicon vias of the same supply net. The first horizontal straps may be electrical connectors in a horizontal direction.

In an aspect, the processor 102 may connect multiple package side bumps with second horizontal straps on the circuit layout plan. The second horizontal straps may facilitate power communication between neighbouring package side bumps of the same supply net. The second horizontal straps may be electrical connectors in a horizontal direction.

In an aspect, the processor 102 may identify corners created by the vertical straps, the first horizontal straps and the second horizontal straps. The corners may have an angle of substantially 90 degrees.

In an aspect, the processor 102 may create diagonal straps on the corners on the circuit layout plan. The diagonal straps may facilitate power communication between neighbouring anchor points of the same supply net. The diagonal straps may be electrical connectors in a diagonal direction.

In an aspect, the processor 102 may determine each length of the vertical straps, the first horizontal straps, the second horizontal straps and the diagonal straps. The processor 102 may compare each length of the vertical straps, the first horizontal straps, the second horizontal straps and the diagonal straps with a predetermined maximum length.

The processor 102 may split each length of the vertical straps, the first horizontal straps, the second horizontal straps and the diagonal straps which exceeds the predetermined maximum length into multiple smaller straps on the circuit layout plan.

In an aspect, the circuit layout plan created by the processor may include one or more specific topology characteristics such as vertical straps aligned to TSV center and package side bump center, alternating side horizontal power grid reinforcements, extra coverage and horizontal connectivity through TSV array structures of the same supply net, and diagonal segments covering corners (e.g., 90 degree angles) of specific length, width and position.

In an aspect, the processor 102 may identify the anchor points and sort them by location and connectivity. The routing implementation algorithm include multiple steps for example 6 steps. Each step may address specific routing requirement related to power grid continuity or layout design rules compliance.

One of the steps may be related to vertical strap creation with alignment to the anchor points: TSV and Package side bumps. In this step, the anchor points are sorted by location. The connectivity of each anchor point is analyzed. Vertical straps may be created continuously through the neighboring anchor points of the same supply net. A break in routing equal to end-to-end distance DRC rule value is created between straps of different supply nets. A gap should be created between the straps of different supply nets to avoid shorted circuit. The gap size is defined by the design rules. The value may be, for example, 8 um.

Another step may be related to horizontal strap creation. In this step, horizontal power grid re-enforcements and additional connections to the package side bumps are created.

Another step may be related to unconnected TSV. This step may identify unconnected neighboring TSVs of the same supply net and connect them with horizontal straps. Also, the processor 102 may calculate the routing strap coordinates to establish full TSV coverage by PSM shape according to a predetermined rule. A PSM_07 rule specifies the dimensions of a PSM layer shape relative to the TSM boundary. The value can be, for example, 3.5 um.

Another step may be related to unconnected side bumps. This step may identify unconnected neighboring side bumps of the same supply net and connect them with horizontal straps.

Another step may be related to identification of corners. In this step, the processor 102 may identify corners and may create diagonal straps in the corners. A predetermined rule, e.g., the PSM_00 rule does not allow PSM layer to form 90 degree corners. This is the reason diagonal shapes created at every 90 degree corner formed by the PSM routing. Another predetermined rule, e.g., PSM_10 rule specifies the min segment length of segments touching 45 degree diagonal segments. The value can be, for example, 2 um.

Another step may be related to maximum length of straps. In this step, may determine each length of the vertical straps, the first horizontal straps, the second horizontal straps and the diagonal straps. The processor 102 may compare each length of the vertical straps, the first horizontal straps, the second horizontal straps and the diagonal straps with a predetermined maximum length. Each strap cannot be longer than specified length. Therefore, straps that are longer than this value need to cut into segments. Each resulting strap needs to be shorter that the specified length. The algorithm chooses an appropriate place to create a cut. New layout may be potentially created if the cut is too close to any other straps overlapping with the straps being cut. So, the algorithm first checks presence of any overlapping straps inside a cut window. If overlapping straps are found, the cut window shifts, and the same check is done again. When a window for a safe cut is identified, the cut is done. To allow this flexibility to shift the cut window, the PSM segment length defined by the algorithm is smaller than the maximum allowed length (PSM_19) by 100 um.

The processor 102 may split each length of the vertical straps, the first horizontal straps, the second horizontal straps and the diagonal straps which exceeds the predetermined maximum length into multiple smaller straps. The PSM_19 rule defines the maximum length of a PSM strap. The value can be, for example, 1500 um.

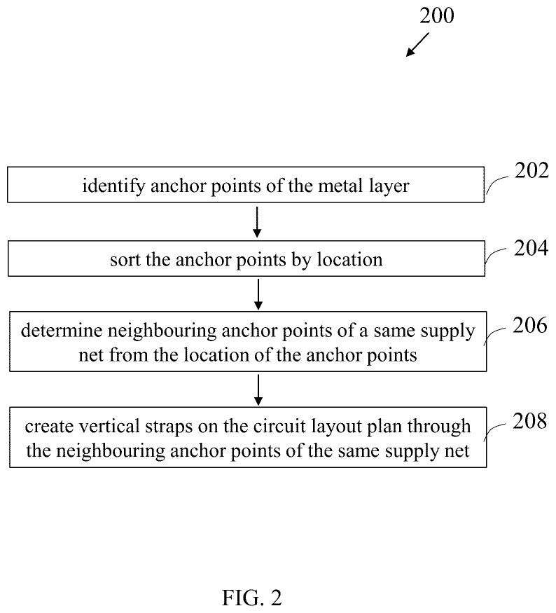

FIG. 2 illustrates a flow diagram for a method for automatically routing a circuit layout of a metal layer of an interposer.

According to various aspects, in step 202, the processor identifies anchor points of the metal layer the anchor points may include through-silicon vias and/or package side bumps on the metal layer.

According to various aspects, in step 204, the processor sorts the anchor points by location.

According to various aspects, in step 206, the processor determines neighbouring anchor points of a same supply net from the location of the anchor points

According to various aspects, in step 208, the processor creates vertical straps on the circuit layout plan through the neighbouring anchor points of the same supply net. The vertical straps may facilitate power communication between neighbouring anchor points of the same supply net.

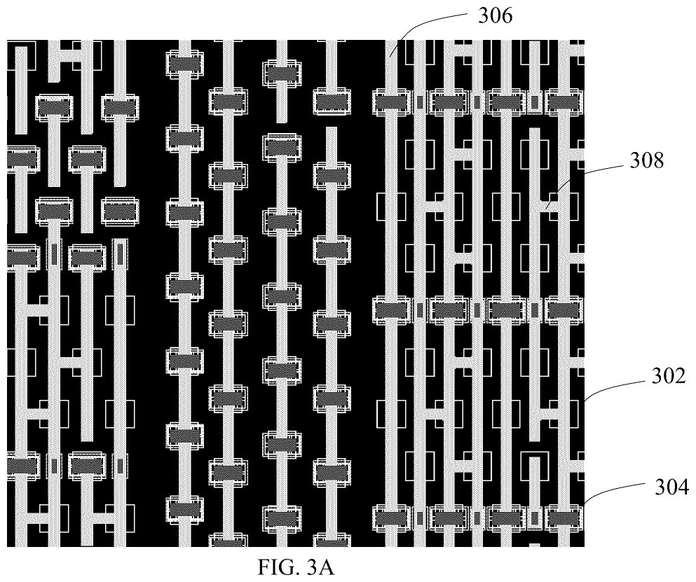

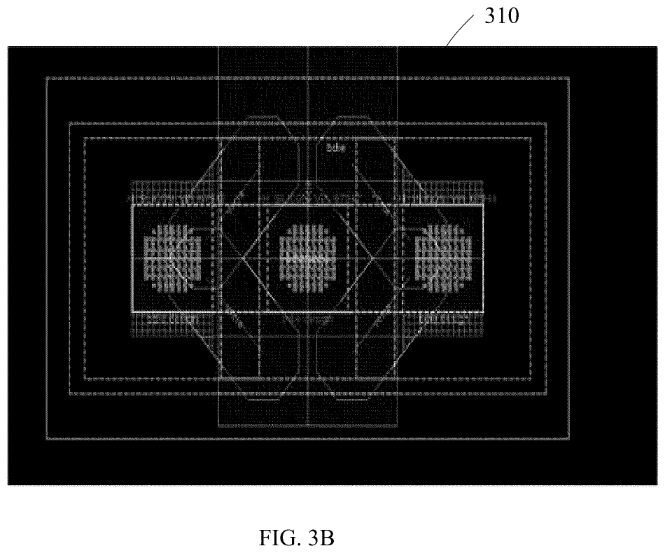

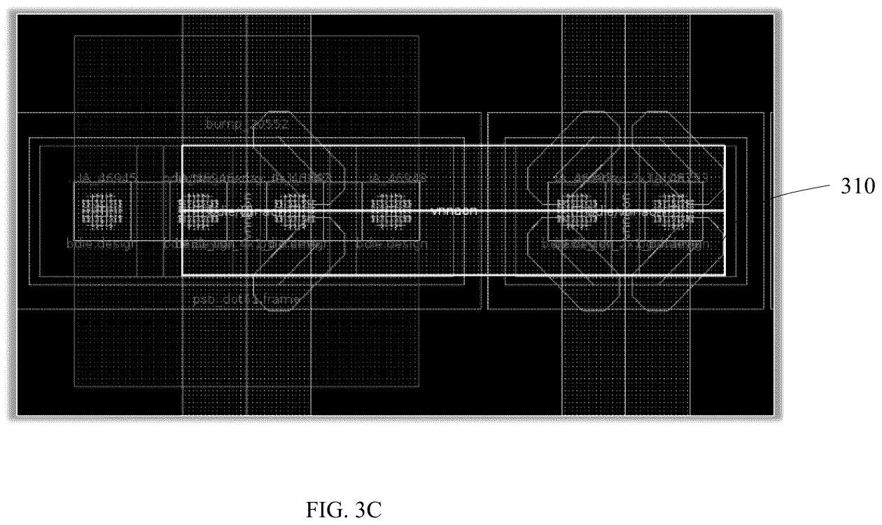

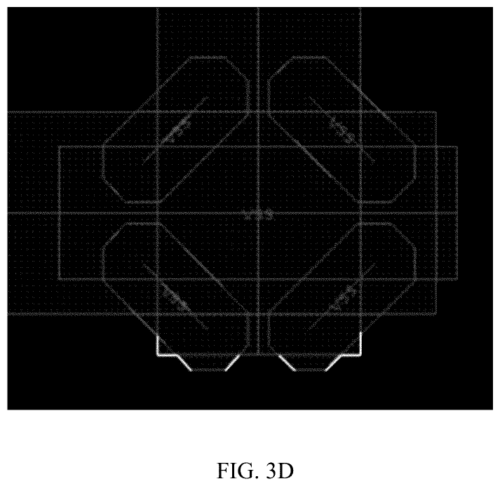

FIGS. 3A to 3D show exemplary circuit layouts of a metal layer of an interposer.

As shown in FIGS. 3A to 3D, the processor identifies through silicon vias 302 and package side bumps 304 and connects them with vertical straps 306, horizontal straps 308 and diagonal straps 310 according to the methods and steps disclosed herein.

### EXAMPLES

The examples set forth herein are illustrative and not exhaustive.

Example 1 is a method for automatically routing a circuit layout plan of a metal layer of an interposer, the method including: identifying anchor points of the metal layer; sorting the anchor points by location; determining neighbouring anchor points of a same supply net from the location of the anchor points; and creating vertical straps on the circuit layout plan through the neighbouring anchor points of the same supply net.

Example 2 may include the method of example 1 and/or any other example disclosed herein, in which the anchor points of the metal layer includes through-silicon vias and package side bumps.

Example 3 may include the method of example 2 and/or any other example disclosed herein, in which the method further includes creating the vertical straps on the circuit layout plan through neighbouring through-silicon vias and neighbouring package side bumps of the same supply net.

Example 4 may include the method of example 3 and/or any other example disclosed herein, in which the method further includes determining neighbouring through-silicon vias of the same supply net and connecting the neighbouring through-silicon vias on the circuit layout plan with first horizontal straps.

Example 5 may include the method of example 4 and/or any other example disclosed herein, in which the method further includes determining neighbouring package side bumps of the same supply net and connecting the neighbouring package side bumps with second horizontal straps on the circuit layout plan.

Example 6 may include the method of example 5 and/or any other example disclosed herein, in which the method further includes identifying corners created by the vertical straps, the first horizontal straps and the second horizontal straps.

Example 7 may include the method of example 6 and/or any other example disclosed herein, in which the method further includes creating diagonal straps on the corners on the circuit layout plan.

Example 8 may include the method of example 7 and/or any other example disclosed herein, in which the method further includes determining each length of the vertical straps, the first horizontal straps, the second horizontal straps and the diagonal straps and comparing each length with a predetermined maximum length.

Example 9 may include the method of example 8 and/or any other example disclosed herein, in which the method further includes splitting each length of the vertical straps, the first horizontal straps, the second horizontal straps and the diagonal straps which exceeds the predetermined maximum length into multiple smaller straps on the circuit layout plan.

Example 10 is a computing device for automatically routing a circuit layout of a metal layer of an interposer, including one or more processor(s) configured to: and: identify anchor points of the metal layer; sort the anchor points by location; determine neighbouring anchor points of a same supply net from the location of the anchor points; and create vertical straps on the circuit layout plan through the neighbouring anchor points of the same supply net.

Example 11 may include the computing device of example 10 and/or any other example disclosed herein, in which the anchor points of the metal layer include through-silicon vias and package side bumps.

Example 12 may include the computing device of example 11 and/or any other example disclosed herein, in which the one or more processor(s) is configured to create the vertical straps on the circuit layout plan through neighbouring through-silicon vias and neighbouring package side bumps of the same supply net.

Example 13 may include the computing device of example 12 and/or any other example disclosed herein, in which the one or more processor(s) is configured to determine neighbouring through-silicon vias of the same supply net and connecting the neighbouring through-silicon vias on the circuit layout plan with first horizontal straps.

Example 14 may include the computing device of example 13 and/or any other example disclosed herein, in which the one or more processor(s) is configured to determine neighbouring package side bumps of the same supply net and connecting the neighbouring package side bumps with second horizontal straps on the circuit layout plan.

Example 15 may include the computing device of example 14 and/or any other example disclosed herein, in which the one or more processor(s) is configured to identify corners created by the vertical straps, the first horizontal straps and the second horizontal straps.

Example 16 may include the computing device of example 15 and/or any other example disclosed herein, in which the one or more processor(s) is configured to create diagonal straps on the corners on the circuit layout plan.

Example 17 may include the computing device of example 16 and/or any other example disclosed herein, in which the one or more processor(s) is configured to determine each length of the vertical straps, the first horizontal straps, the second horizontal straps and the diagonal straps and comparing each length with a predetermined maximum length.

Example 18 may include the computing device of example 17 and/or any other example disclosed herein, in which the one or more processor(s) is configured to split each length of the vertical straps, the first horizontal straps, the second horizontal straps and the diagonal straps which exceeds the predetermined maximum length into multiple smaller straps on the circuit layout plan.

Example 19 may include the computing device of example 10 and/or any other example disclosed herein, in which the computing device further includes an optical instrument electrically connected to the one or more processors, wherein the optical instrument is configured to provide location information of the anchor points to the one or more processors.

Example 20 may include a non-transitory computer-readable medium for automatically routing a circuit layout plan of a metal layer of an interposer comprising instructions, which, if executed by one or more processors, are configured to cause the one or more processors to: identify anchor points of the metal layer; sort the anchor points by location; determine neighbouring anchor points of a same supply net from the location of the anchor points; and create vertical straps on the circuit layout plan through the neighbouring anchor points of the same supply net.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for automatically routing a circuit layout plan of a metal layer of an interposer, the method comprising:
identifying anchor points of the metal layer;
sorting the anchor points by location;
determining neighbouring anchor points of a same supply net from the location of the anchor points; and
creating vertical straps on the circuit layout plan through the neighbouring anchor points of the same supply net.

2. The method of claim 1, wherein the anchor points of the metal layer comprise through-silicon vias and package side bumps.

3. The method of claim 2, further comprising:
creating the vertical straps on the circuit layout plan through neighbouring through-silicon vias and neighbouring package side bumps of the same supply net.

4. The method of claim 3, further comprising:
determining neighbouring through-silicon vias of the same supply net and connecting the neighbouring through-silicon vias on the circuit layout plan with first horizontal straps.

5. The method of claim 4, further comprising:
determining neighbouring package side bumps of the same supply net and connecting the neighbouring package side bumps with second horizontal straps on the circuit layout plan.

6. The method of claim 5, further comprising:
identifying corners created by the vertical straps, the first horizontal straps and the second horizontal straps.

7. The method of claim 6, further comprising:
creating diagonal straps on the corners on the circuit layout plan.

8. The method of claim 7, further comprising:
determining each length of the vertical straps, the first horizontal straps, the second horizontal straps and the diagonal straps and comparing each length with a predetermined maximum length.

9. The method of claim 8, further comprising:
splitting each length of the vertical straps, the first horizontal straps, the second horizontal straps and the diagonal straps which exceeds the predetermined maximum length into multiple smaller straps on the circuit layout plan.

10. A computing device for automatically routing a circuit layout plan of a metal layer of an interposer, comprising:
one or more processors, configured to:
identify anchor points of the metal layer;
sort the anchor points by location;
determine neighbouring anchor points of a same supply net from the location of the anchor points; and
create vertical straps on the circuit layout plan through the neighbouring anchor points of the same supply net.

11. The computing device of claim 10, wherein the anchor points of the metal layer comprise through-silicon vias and package side bumps.

12. The computing device of claim 11, wherein the one or more processors are further configured to create the vertical straps on the circuit layout plan through neighbouring through-silicon vias and neighbouring package side bumps of the same supply net.

13. The computing device of claim 12, wherein the one or more processors are further configured to determine neighbouring through-silicon vias of the same supply net and connecting the neighbouring through-silicon vias on the circuit layout plan with first horizontal straps.

14. The computing device of claim 13, wherein the one or more processors are further configured to determine neighbouring package side bumps of the same supply net and connecting the neighbouring package side bumps with second horizontal straps on the circuit layout plan.

15. The computing device of claim 14, wherein the one or more processors are further configured to identify corners created by the vertical straps, the first horizontal straps and the second horizontal straps.

16. The computing device of claim 15, wherein the one or more processors are further configured to create diagonal straps on the corners on the circuit layout plan.

17. The computing device of claim 16, wherein the one or more processors are further configured to determine each length of the vertical straps, the first horizontal straps, the second horizontal straps and the diagonal straps and comparing each length with a predetermined maximum length.

18. The computing device of claim 17, wherein the one or more processors are further configured to split each length of the vertical straps, the first horizontal straps, the second horizontal straps and the diagonal straps which exceeds the predetermined maximum length into multiple smaller straps on the circuit layout plan.

19. The computing device of claim 10, further comprising:
an optical instrument electrically connected to the one or more processors, wherein the optical instrument is configured to provide location information of the anchor points to the one or more processors.

20. A non-transitory computer-readable medium for automatically routing a circuit layout plan of a metal layer of an interposer, comprising instructions, which, if executed by one or more processors, are configured to cause the one or more processors to:
identify anchor points of the metal layer;
sort the anchor points by location;
determine neighbouring anchor points of a same supply net from the location of the anchor points; and
create vertical straps on the circuit layout plan through the neighbouring anchor points of the same supply net.
